(19) United States
(12) Patent Application Publication
(10) Pub. No.: US 2021/0313148 A1
(43) Pub. Date: Oct. 7, 2021

(54) PLASMA ETCHING METHOD AND PLASMA PROCESSING APPARATUS

(71) Applicant: Tokyo Electron Limited, Tokyo (JP)

(72) Inventors: Kosuke OGASAWARA, Miyagi (JP); Shuhei YOSHIBA, Miyagi (JP); Takanori BANSE, Miyagi (JP)

(21) Appl. No.: 17/353,960

(22) Filed: Jun. 22, 2021

Related U.S. Application Data
(63) Continuation of application No. 16/381,218, filed on Apr. 11, 2019, now abandoned.

(30) Foreign Application Priority Data
Apr. 23, 2018 (JP) 2018-082443

(51) Int. Cl. H01J 37/32; H01L 21/3065

(52) U.S. Cl. CPC H01J 37/32091; H01J 37/32165; H01J 37/32458; H01J 37/32642; H01L 21/3065; H01J 2237/334; H01J 37/32449

(57) ABSTRACT

A plasma etching method performed by a plasma processing apparatus is provided. The plasma processing apparatus includes an edge ring which includes an inner edge ring provided in a vicinity of a substrate to be placed on a stage, a middle edge ring arranged outside the inner edge ring, the middle edge ring being configured to be moved vertically by an actuation mechanism, and an outer edge ring arranged outside the middle edge ring. The method includes: performing first etching based on a first process condition; performing second etching based on a second process condition different from the first process condition; and moving the middle edge ring by the actuation mechanism, the moving being performed after the first etching is performed and before the second etching is performed.

### CROSS-REFERENCE TO RELATED APPLICATIONS

This patent application is a continuation application of U.S. patent application Ser. No. 16/381,218 filed on Apr. 11, 2019, which is based on and claims priority to Japanese Patent Application No. 2018-082443 filed on Apr. 23, 2018, the entire contents of which are incorporated herein by reference.

### BACKGROUND OF THE INVENTION

### 1. Field of the Invention

The present disclosure relates to a plasma etching method and a plasma processing apparatus.

### 2. Description of the Related Art

In a plasma etching apparatus, an edge ring is provided around an outer circumference of a wafer (see Patent Document 1, for example). The edge ring controls plasma in a vicinity of the outer circumference of the wafer, and improves uniformity of an etching rate on a surface of the wafer.

An etching rate at an edge of the wafer varies depending on a height of the edge ring. Thus, as the edge ring is abraded and the height varies, control of etching characteristics at the edge of the wafer such as an etching rate becomes difficult. Thus, Patent Document 1 describes a technique for improving controllability of etching characteristics at an edge of a wafer, by providing an actuator for moving an edge ring up and down, to control a position of an upper surface of the edge ring.

However, in the technique disclosed in Patent Document 1, out of two pieces of edge rings, an edge ring positioned in an inner side is fixed, and only an edge ring at an outer side is moved up and down. In such a technique, by moving up and down the edge ring at the outer side, an etching rate of the entirety of a wafer varies. That is, etching characteristics at not only an edge portion of a wafer but also an entirety of the wafer vary.

### CITATION LIST

### Patent Document

[Patent Document 1] Japanese Laid-open Patent Application Publication No. 2008-244274

### SUMMARY OF THE INVENTION

In one aspect, the present disclosure aims at providing a technique for controlling an etching state.

According to an aspect of the present disclosure, a plasma etching method performed by a plasma processing apparatus is provided. The plasma processing apparatus includes an edge ring which includes an inner edge ring provided in a vicinity of a substrate to be placed on a stage, a middle edge ring arranged outside the inner edge ring, the middle edge ring being configured to be moved vertically by an actuation mechanism, and an outer edge ring arranged outside the middle edge ring. The method includes: performing first etching based on a first process condition; performing second etching based on a second process condition different from the first process condition; and moving the middle edge ring by the actuation mechanism, the moving being performed after the first etching is performed and before the second etching is performed.

### BRIEF DESCRIPTION OF THE DRAWINGS

FIG. 1 is a diagram illustrating an example of a plasma processing apparatus according to an embodiment;

FIG. 2 is a diagram illustrating an edge ring, an actuation mechanism, and an actuating unit according to the embodiment;

FIGS. 3A and 3B are diagrams illustrating vertical movement of the edge ring according to the embodiment;

FIG. 4 is a diagram illustrating a mechanism of plasma generation;

FIGS. 5A to 5C are diagrams illustrating an example of an experimental result about a relationship between a thickness of the edge ring according to the embodiment and etching characteristics;

FIG. 6 is a diagram describing an experiment in FIG. 5;

FIGS. 7A to 7C are diagrams illustrating an example of an experimental result about a relationship between vertical displacement of a middle edge ring according to the embodiment and an etching characteristic;

FIGS. 8A and 8B are diagrams illustrating an example of correlation information of vertical displacement of the middle edge ring according to the embodiment embodiment and an etching characteristic;

FIG. 9 is a flowchart illustrating a process of collecting the correlation information of the vertical displacement of the middle edge ring according to the embodiment and the etching characteristic;

FIG. 10A illustrates an example of collected correlation information according to the embodiment;

FIG. 10B and FIG. 10C are diagrams illustrating another example of vertical movement of the edge ring;

FIG. 11 is a flowchart illustrating an example of an etching process according to the embodiment; and

FIGS. 12A to 12C are diagrams illustrating variations of vertical movements of edge rings.

### DETAILED DESCRIPTION OF EMBODIMENTS

In the following, embodiments of the present disclosure will be described with reference to the drawings. Note that in the following descriptions and the drawings, elements having substantially identical features are given the same reference symbols and overlapping descriptions may be omitted.

### Plasma Processing Apparatus

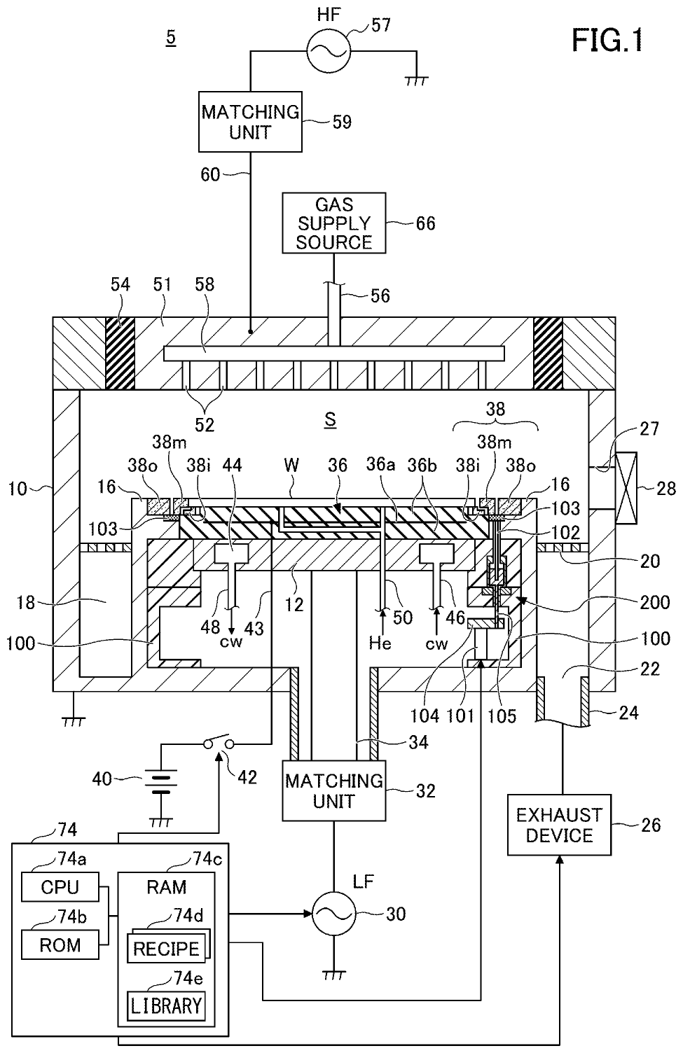

First, an example of a plasma processing apparatus 5 according to an embodiment will be described with reference to FIG. 1. FIG. 1 is a diagram illustrating a structure of the plasma processing apparatus 5 according to the embodiment. The present embodiment describes a case in which the plasma processing processing apparatus 5 is a capacitively coupled plasma type parallel-flat plate plasma processing apparatus.

The plasma processing apparatus 5 includes a cylindrical processing vessel 10 which is a cylindrical vacuum vessel made from metal such as aluminum or stainless steel. An inside of the processing vessel 10 is a processing chamber for Performing a plasma process. The processing vessel 10 is grounded.

A disc shaped stage 12 is provided at a center of a lower portion in the processing vessel 10. The stage 12 is made from aluminum, for example. The stage 12 is supported by a cylindrical supporting member 16 that extends upward from the bottom of the processing vessel 10, and by a housing 100 adjacently provided at an inside of the cylindrical supporting member 16.

Between the cylindrical supporting member 16 and a side wall of the processing vessel 10, an annular exhaust path 18 is formed. At an upper portion or an entrance of the exhaust path 18, an annular baffle plate 20 is provided. At a bottom of the exhaust path 18, at least one exhaust port 22 is provided. In order to make gas flow in the processing vessel 10 axially symmetrical with a central axis of a wafer W on the stage 12, it is preferable that multiple exhaust ports 22 are provided at regular intervals in a circumferential direction.

An exhaust device 26 is connected to each of the exhaust ports 22 via an exhaust pipe 24. The exhaust device 26 includes a vacuum pump such as a turbomolecular pump, and can reduce pressure of a Plasma generating space S in the processing vessel 10 to a desirable quality of vacuum. Further, a gate valve 28 is provided at the side wall of the processing vessel 10, which is used for opening and/or closing a loading/unloading port 27 for a wafer W.

A second high frequency power source 30 is electrically connected to the stage 12 via a matching unit 32 and a feeder rod 34. The second high frequency power source 30 supplies high frequency electric power LF of a frequency suitable for controlling energy of ions to be attracted to a wafer W (such as radio frequency at 13.56 MHz). The high frequency electric power LF output from the second high frequency power source 30 is variable. As the high frequency electric power LF is applied to the stage 12, the stage 12 functions as a lower electrode. The matching unit 32 includes a variable reactance matching circuit to cause impedance of the second high frequency power source 30 to match impedance of a load.

An electrostatic chuck 36 is provided on an upper surface of the stage 12. The electrostatic chuck 36 is made by sandwiching an electrode 36a formed of a conductive film between a pair of insulating films 36b. A direct-current (DC) power source 40 is electrically connected to the electrode 36a via a switch 42 and a coated wire 43. The electrostatic chuck 36 generates electrostatic force by DC voltage supplied from the DC power source 40, and a wafer W is attracted to and held by the electrostatic chuck 36 by the generated electrostatic force.

An edge ring 38 is disposed along an outer circumference of a wafer W placed on the stage 12. The edge ring 38 controls plasma in a vicinity of the outer circumference of the wafer W, and improves uniformity of an etching rate on a surface of the wafer W. The edge ring 38 is composed of three separate rings, an inner edge ring 38i, a middle edge ring 38m, and an outer edge ring 38o.

In the stage 12, an annular coolant passage 44 extending in a circumferential direction is provided. From a chiller unit, coolant at a predetermined temperature, such as cooling water cw, is supplied to the coolant passage 44, and the coolant circulates in the coolant passage 44 via pipes 46 and 48, in order to control a temperature of a wafer W placed on the electrostatic chuck 36. Further, heat transmitting gas such as He gas is supplied to a space between an upper surface of the electrostatic chuck 36 and a bottom surface of the wafer W, from a heat transmitting gas supply unit via a gas supply pipe 50. Also, a lift pin and an elevation mechanism of the lift pin are provided at the stage 12. The lift pin can move up and down, and is used for loading and unloading a wafer. The lift pin is provided so as to penetrate the stage in a vertical direction.

A gas shower head 51 is mounted at a ceiling of the processing vessel 10, via a shield ring 54 provided at a periphery of the gas shower head 51. The gas shower head 51 is formed of silicon. The gas shower head 51 also acts as an opposing electrode (upper electrode) facing the stage 12 (lower electrode).

A gas inlet 56 for introducing gas is formed at the gas shower head 51. Inside the gas shower head 51, a diffusion chamber 58 connected to the gas inlet 56 is provided. Gas output from a gas supply source 66 is supplied to the diffusion chamber 58 via the gas inlet 56, and diffuses in the diffusion chamber 58. Then the gas is introduced from the large number of gas holes 52 to the plasma generating space S.

A first high frequency power source 57 is electrically connected to the gas shower head 51 via a matching unit 59 and a feeder rod 60. The first high frequency power source 57 outputs high frequency electric power HF of a frequency suitable for generating plasma by high frequency discharge (such as radio frequency at 40 MHz), which is higher than that of the high frequency electric power LF output from the second high frequency power source 30. The first high frequency power source 57 can output the high frequency electric power HF by a variable amount. The matching unit 59 includes a variable reactance matching circuit to cause impedance of the first high frequency power source 57 to match impedance of a load.

The plasma processing apparatus 5 includes a control unit 74. The control unit 74 includes a CPU 74a, a ROM 74b, and a RAM 74c, for example. The ROM 74b stores a basic program used by the CPU 74a controlling an entirety of the plasma processing apparatus 5, and various types of data.

In the RAM 74c, multiple recipes 74d each corresponding to a different process condition are stored. The control unit 74 controls operations of each component of the plasma processing apparatus 5 and an operation of the entirety of the plasma processing apparatus 5, in accordance with the recipe 74d corresponding to a process condition. Examples of components of the plasma processing apparatus 5 include the exhaust device 26, the first high frequency power source 57, the second high frequency power source 30, the matching unit 32, the matching unit 59, the switch 42 for the electrostatic chuck, the gas supply source 66, a chiller unit, and the heat transmitting gas supply unit.

The RAM 74c also stores a library 74e recording correlation information about a relationship between a vertical movement amount of the middle edge ring 38m and an etching rate of each different location of a wafer W in a radial direction. The correlation information is collected for each process condition in advance. The library 74e may be stored in the ROM 74b. The RAM 74c or the ROM 74b is an example of a memory unit storing, in each process condition, correlation information of a movement amount of the middle edge ring 38m and an etching rate of a wafer W. Also, the etching rate used in the correlation information is an example of a value indicating an etching characteristic.

When an etching process is performed in the plasma processing apparatus 5, the gate valve 28 is opened first, a wafer W is loaded into the processing vessel 10, and the wafer W is placed on the electrostatic chuck 36. Subsequently, after the gate valve 28 is closed, a predetermined gas is introduced from the gas supply source 66 to the processing vessel 10, at a predetermined flow rate or a flow ratio of gases, and pressure in the processing vessel 10 is reduced to a predetermined value by the exhaust device 26. Further, the first high frequency power source 57 is turned on to output the high frequency electric power HF for generating plasma at predetermined magnitude, and to supply the high frequency electric power HF to the gas shower head 51 via the matching unit 59 and the feeder rod 60.

When the high frequency electric power LF for attracting ions is applied, the second high frequency power source 30 is turned on to output the high frequency electric power LF at predetermined magnitude, and to supply the high frequency electric power LF to the stage 12 via the matching unit 32 and the feeder rod 34. Further, heat transmitting gas is supplied to a space between the electrostatic chuck 36 and the wafer W, from the heat transmitting gas supply unit. In addition, the switch 42 is turned on, to apply DC voltage to the electrode 36a of the electrostatic chuck 36, to cause the wafer to be attracted to and held by the electrostatic chuck 36 by electrostatic force, and to enclose the heat transmitting gas between the wafer W and the electrostatic chuck 36.

### 3-Piece Edge Ring

An etching rate at an edge of a wafer W varies depending on a height of the edge ring 38. Thus, as the edge ring 38 is abraded and the height varies, an etching rate at the edge of the wafer W varies, and control of etching characteristics at the edge becomes difficult.

Thus, the edge ring 38 according to the present embodiment is composed of three pieces. That is, the edge ring 38 includes the inner edge ring 38i, the middle edge ring 38m, and the outer edge ring 38o. By an actuation mechanism 200, the middle edge ring 38m of the edge ring 38 is moved vertically (moved up and down), and thereby an etching state of an edge of a wafer W is controlled. The actuation mechanism 200 includes a pusher pin 102. The pusher pin 102 moves vertically by a driving force of a piezo actuator 101 via a member 104a and a bushing 105. In accordance with movement of the pusher pin 102, a connecting member 103 moves vertically, and thereby the middle edge ring 38m connected to the connecting member 103 moves vertically. Note that, in the present embodiment, a ring-shaped portion of a wafer W approximately 140 mm to 148 mm away from a center of the wafer W is referred to as an edge portion of the wafer W.

### Edge Ring Structure

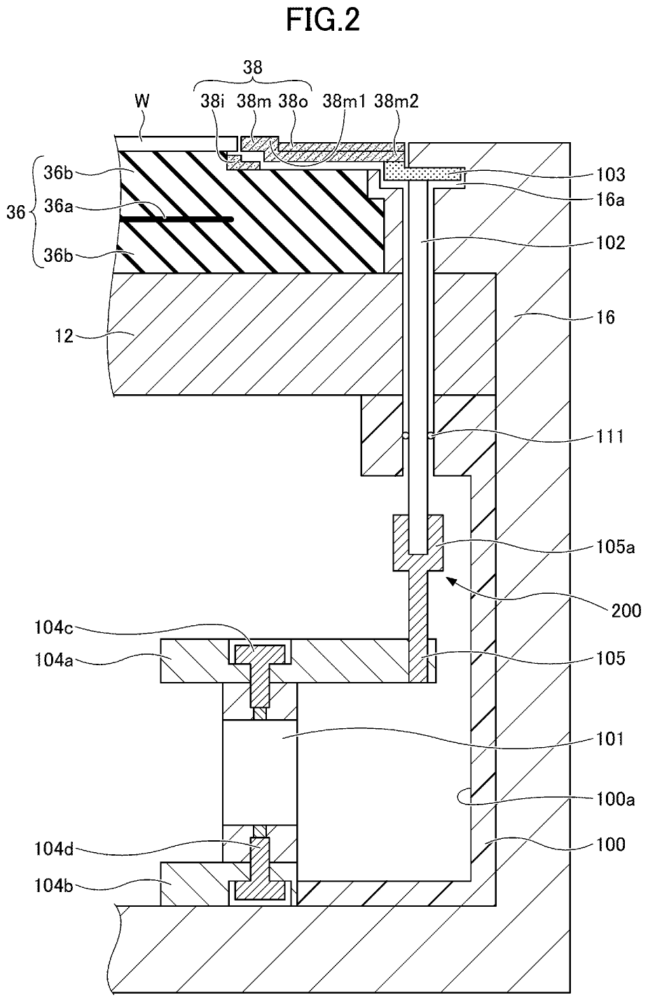

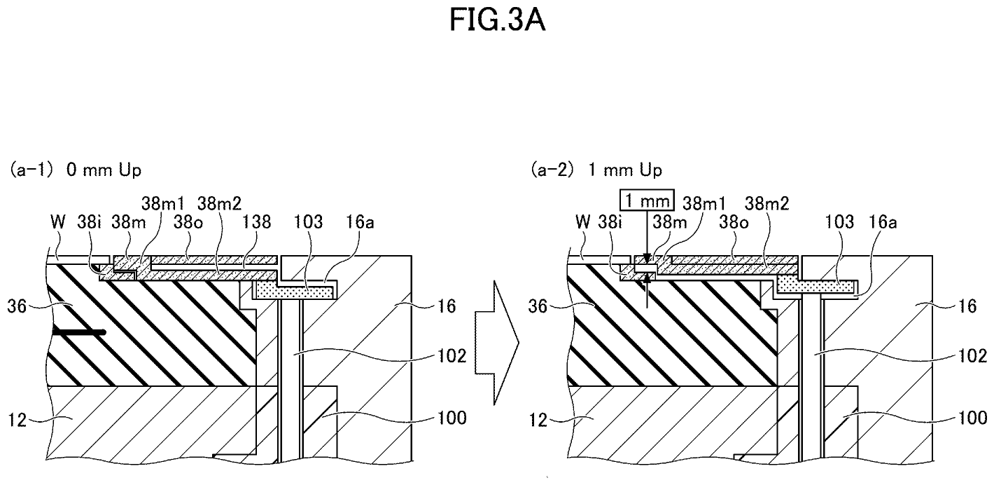

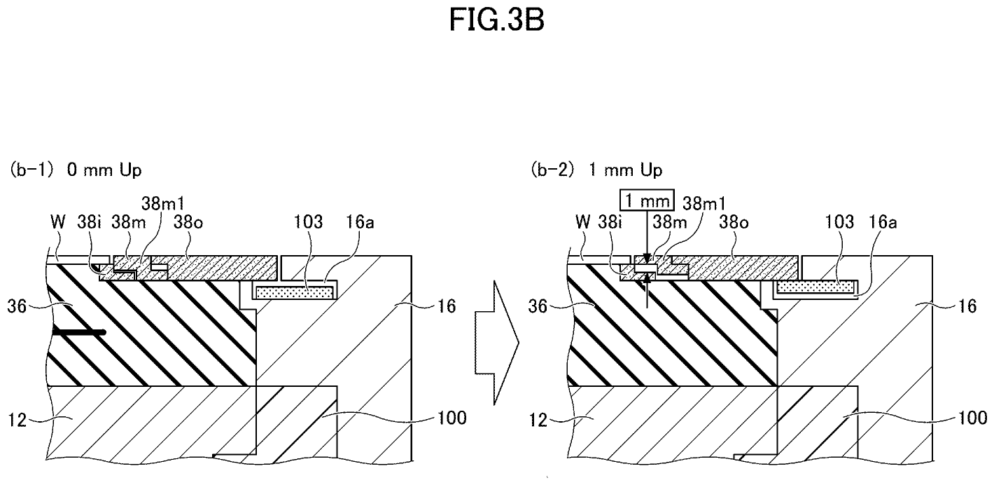

Next, a structure of the edge ring 38 and its peripheral parts will be described with reference to FIG. 2. Also, vertical movement of the middle edge ring 38m will be described with reference to FIGS. 3A and 3B. FIG. 2 is an enlarged view of a cross section of an example of the edge ring 38 and its vicinity according to the present embodiment. FIGS. 3A and 3B are diagrams illustrating vertical movement of the edge ring 38 according to the present embodiment.

In FIG. 2, the edge ring 38, the actuation mechanism 200, and the piezo actuator 101 according to the present embodiment are illustrated. The inner edge ring 38i is an innermost member of the edge ring 38, which is provided in a vicinity of an outer circumference of a wafer W, so as to surround the wafer W below the wafer W. The middle edge ring 38m is a member provided outside the wafer W and the inner edge ring 38i, so as to surround the wafer W and the inner edge ring 38i. The outer edge ring 38o is an outermost member of the edge ring 38, which is provided outside the middle edge ring 38m. In the present embodiment, the inner edge ring 38i and the outer edge ring 38o are fixed on the upper surface of the electrostatic chuck 36. The middle edge ring 38m is configured to be movable vertically by the actuation mechanism 200.

The middle edge ring 38m includes a ring portion 38m1 surrounding a periphery of the wafer W, and three tabs 38m2. The tabs 38m2 are rectangular members projecting outward from the ring portion 38m1, and are arranged at an outer circumference of the ring portion 38m1 at regular intervals. A vertical cross section (a cross section taken along the vertical direction) is of an L-shape. In a case in which the middle edge ring 38m is moved upward from a state in which an L-shaped step of the ring portion 38m1 is in contact with a step of the inner edge ring 38i having an L-shaped vertical cross section, the step of the ring portion 38m1 becomes apart from the step of the inner edge ring 38i.

### Actuation Mechanism and Actuating Unit

The tab 38m2 of the middle edge ring 38m is connected to the annular connecting member 103. The connecting member 103 vertically moves in a space 16a provided in the cylindrical supporting member 16.

The housing 100 is made from insulating material such as alumina. The housing 100 is adjacently provided inside the cylindrical supporting member 16 such that a side surface and a bottom surface of the housing 100 touch the cylindrical supporting member 16. The actuation mechanism 200 is provided in a recess 100a formed inside the housing 100.

The actuation mechanism 200 is for moving the middle edge ring 38m vertically, and includes the pusher pin 102 and the bushing 105. The actuation mechanism 200 is fitted to the housing 100 provided at an outer circumference of a bottom surface of the stage 12, and is configured to be moved vertically by the driving force of the piezo actuator 101. The pusher pin 102 may be formed of sapphire.

The pusher pin 102 penetrates the housing 100 and the stage 12, and is in contact with a bottom surface of the connecting member 103. The bushing 105 is fitted to the member 104a provided inside the housing 100. In a hole for the pusher pin 102, an O ring 111 for separating vacuum space from atmosphere is provided.

To a recess 105a provided at a tip of the bushing 105, a bottom end of the pusher pin 102 is fitted from above. When the bushing 105 moves vertically via the member 104a by a positioning operation of the piezo actuator 101, the pusher pin 102 moves vertically, and the pusher pin 102 pushes the bottom surface of the connecting member 103 upward, or pulls the bottom surface of the connecting member 103 downward. Accordingly, the middle edge ring 38m moves vertically via the connecting member 103.

The piezo actuator 101 is an element for positioning, which utilizes piezoelectric effect, and can perform positioning at a resolution of 0.006 mm (6 μm). The pusher pin 102 moves vertically in accordance with an amount of vertical displacement of the piezo actuator 101. Accordingly, the middle edge ring 38m moves vertically by 0.006 mm unit at minimum.

For each of the three tabs 38m2 arranged on the circumference of the ring portion 38m1 at regular intervals in the circumferential direction, the corresponding pusher pin 102 is provided. For each of the pusher pins 102, the corresponding piezo actuator 101 is provided. The member 104a and a member 104b are annular members, and the member 104b is positioned below the member 104a. Each of the three piezo actuators 101 is disposed between the members 104a and 104b and fixed to the housing 100, such that an upper end of each of the three piezo actuators 101 is bolted to the member 104a with a screw 104c, and a bottom end of each of the three piezo actuators 101 is bolted to the member 104b with a screw 104d. According to the aforementioned structure, the pusher pins 102 push the middle edge ring 38m at three points, via the annular connecting member 103. Note that the piezo actuator 101 according to the present embodiment is an example of an actuating unit.

On a bottom surface of the outer edge ring 38o, recesses are formed at locations corresponding to the tabs 38m2. When the pusher pins 102 push the middle edge ring 38m upward, the tabs 38m2 are fitted into the recesses. According to this structure, the middle edge ring 38m can be moved upward while the outer edge ring 38o is fixed.

According to the structure described above, the stage 12 and the electrostatic chuck 36 are supported by the housing 100, and the actuation mechanisms 200 and the actuating units are fitted to the housing 100. Accordingly, the middle edge ring 38m can be moved vertically by using the existing electrostatic chuck 36, without requiring a design modification of the electrostatic chuck 36.

Also, in the present embodiment, because a predetermined space is provided between the upper surface of the electrostatic chuck 36 and the bottom surface of the middle edge ring 38m as illustrated in FIG. 2, the middle edge ring 38m can be moved to not only an upward direction but also a downward direction. Accordingly, the middle edge ring 38m can be moved in the predetermined space to not only an upward direction but also a downward direction by a predetermined amount. Because the middle edge ring 38m can be moved to not only an upward direction but also a downward direction, a range of controlling a sheath can be extended.

However, an actuating unit is not limited to the piezo actuators 101, and a motor capable of performing positioning control at a resolution of 0.006 mm may be used as an actuating unit. Also, the number of actuating units may be one, or more than one. Further, a motor for vertically moving a pusher pin used for raising a wafer W may be used as an actuating unit for moving the middle edge ring 38m. In this case, a mechanism, such as a gear or a driving force switching unit, for switching a destination of transmitting a driving force of the motor between the pusher pin used for raising a wafer W and the pusher pin 102 for the middle edge ring 38m, is required. Also, a mechanism for controlling vertical movement of the pusher pin 102 at a resolution of 0.006 mm is required. However, as a diameter of the middle edge ring 38m arranged around an outer circumference of a 300 mm wafer W is large, approximately 310 mm, an actuating unit for the pusher pin 102 and an actuating unit for the pusher pin used for raising a wafer W are preferably separate.

The control unit 74 may control positioning of the piezo actuators 101 such that a vertical displacement amount of the piezo actuators 101 is in accordance with amount of abrasion of the middle edge ring 38m. However, the control unit 74 may control a vertical displacement amount of the piezo actuators 101 independently of amount of abrasion of the middle edge ring 38m, and may control the middle edge ring 38m to move vertically so as to obtain a desired etching rate.

In a case in which an upper surface of a wafer W and an upper surface of the edge ring 38 are at the same level, a height of a sheath on the wafer W and a height of a sheath on the edge ring 38 during an etching process can become the same. By the height of the sheath being the same at both locations, uniformity of an etching rate on a surface of a wafer W can be improved.

In a case in which a brand-new edge ring 38 is used, because a height of a sheath on the wafer W during an etching process and a height of a sheath on the edge ring 38 are the same, an etching rate on a surface of the wafer W becomes uniform. In this case, as illustrated in a diagram (a-1) of FIG. 3A and a diagram (b-1) of FIG. 3B, the middle edge ring 38m is not moved upward (0 mm) by the pusher pins 102.

However, when the edge ring 38 is abraded by a plasma process such as etching, a height of the sheath on the edge ring 38 becomes lower than a height of the sheath on the wafer W. In this case, an etching rate at an edge portion of the wafer W may rise suddenly, or tilting may occur in an etching profile. The tilting in an etching profile means a phenomenon in which a sheath on an edge portion of a wafer W is inclined because of abrasion of an edge ring, in which ions are introduced to the wafer W from an oblique direction, and in which an etching profile becomes not vertical but slanted.

Thus, in the present embodiment, the middle edge ring 38m may be raised in accordance with amount of abrasion of the edge ring 38. By raising the middle edge ring 38m, a height of the sheath on the wafer W and a height of the sheath on the edge ring 38 can be made to be uniform. Accordingly, occurrence of a sharp increase of an etching rate at the edge portion of the wafer W, or tilting in the etching profile can be avoided.

For example, in a case in which an amount of movement of the middle edge ring 38m is determined to be equal to amount of abrasion of the middle edge ring 38m, if amount of abrasion of the middle edge ring 38m is 1.0 mm, an amount of movement of the middle edge ring 38m in accordance with amount of abrasion is 1.0 mm. Thus, in this case, positioning of the piezo actuator 101 is performed such that the middle edge ring 38m is moved upward by 1.0 mm. As a result, as illustrated in a diagram (a-2) of FIG. 3A and a diagram (b-2) of FIG. 3B, the middle edge ring 38m is moved upward by 1.0 mm.

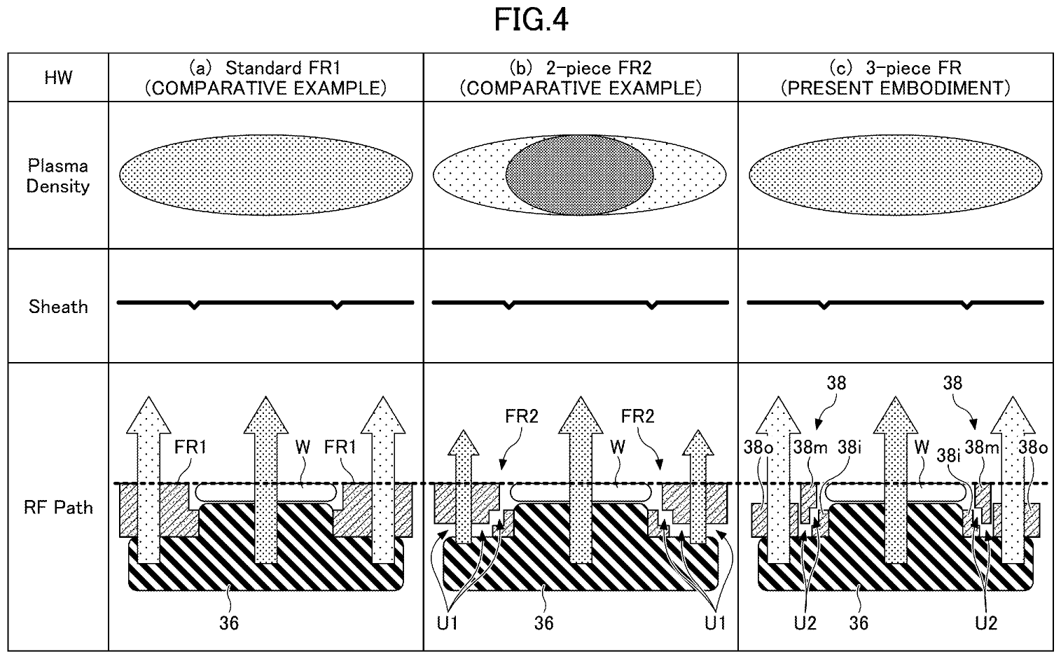

Next, an operation of the edge ring 38 and a state of generated plasma will be described with reference to FIG. 4. A column (a) (column of “Standard FR1 (COMPARATIVE EXAMPLE)”) in FIG. 4 schematically illustrates a plasma generating mechanism when using an edge ring FR1 according to Comparative Example 1, a column (b) (column of “2-piece FR2 (COMPARATIVE EXAMPLE)”) in FIG. 4 schematically illustrates a plasma generating mechanism when using an edge ring FR2 according to Comparative Example 2, and column (c) (column of “3-piece FR (PRESENT EMBODIMENT)”) in FIG. 4 schematically illustrates a plasma generating mechanism when using the edge ring 38 according to the present embodiment.

A row “Plasma Density” in FIG. 4 illustrates states of plasma in Comparative Examples 1 and 2, and in the present embodiment. A row “Sheath” in FIG. 4 illustrates states of sheathes in Comparative Examples 1 and 2, and in the present embodiment. A row “RF Path” in FIG. 4 illustrates flow of high frequency electric power flowing through the electrostatic chuck 36, the edge ring FR1 according to Comparative Example 1, the edge ring FR2 according to Comparative Example 2, and the edge ring 38 according to the present embodiment.

In a case in which the unseparated edge ring FR1 according to Comparative Example 1 is used, if the edge ring FR1 has not abraded, a flat sheath is generated, as illustrated in the column (a) of FIG. 4. In this case, by the high frequency electric power HF output from the first high frequency power source 57, the amount of current flowing through the electrostatic chuck 36 in the middle position becomes approximately the same as the amount of current flowing through the edge ring FR1 located outside the electrostatic chuck 36.

Thus, density of plasma generated in the plasma generating space S becomes approximately uniform. As the edge ring FR1 abrades, a sharp increase of an etching rate at an edge portion of a wafer W occurs.

Next, a case in which the 2-piece edge ring FR2 according to Comparative Example 2 is used, and in which an outer edge ring has been moved upward, will be described. In this case, as illustrated in the column (b) of FIG. 4, when a sheath is flat, with respect to electrical current caused to flow by the high frequency electric power HF for plasma generation, the amount of current flowing through the electrostatic chuck 36 becomes larger than the amount of current flowing through the edge ring FR2. The reason will be explained in the following.

When the outer edge ring is moved upward, a space U1 is formed under the outer edge ring and capacitance is generated at the space U1. The capacitance generated at the space U1 inhibits flow of electric current at the edge ring FR2. Thus, larger current tends to flow through the electrostatic chuck 36 than the edge ring FR2. That is, in the case of the column (b) in FIG. 4, larger current flows through the electrostatic chuck 36 as compared with the case of the column (a), and density of plasma generated in the plasma generating space S becomes larger in the center. Accordingly, when the edge ring FR2 is used, as the outer edge ring is moved to a higher position, an etching rate on an entire surface of a wafer W becomes higher.

On the other hand, as illustrated in the column (c) of FIG. 4, in a case in which the edge ring 38 according to the present embodiment is used, if a height of a sheath is the same on the edge ring 38 and on the electrostatic chuck 36, with respect to electric current caused to flow by the high frequency electric power HF, the amount of current flowing through the electrostatic chuck 36 becomes approximately the same as the amount of current flowing through the edge ring 38.

This is because, in order that only a minimum space U2 is formed in a vicinity of an edge of a wafer W when the middle edge ring 38m is raised, the edge ring 38 according to the present embodiment is composed of three separate pieces, and is configured such that only the middle edge ring 38m is moved vertically. Because the edge ring 38 is configured as described here, capacitance generated at the space U2 is reduced to minimum, and the amount of current flowing through the electrostatic chuck 36 can be made to be approximately the same as the amount of current flowing through the edge ring 38. As a result, density of plasma generated in the Plasma generating space S becomes approximately uniform. Thus, an etching rate at an edge of a wafer W can be controlled without shifting an etching rate on an entire surface of the wafer W.

### Edge Ring Thickness and Etching Characteristics

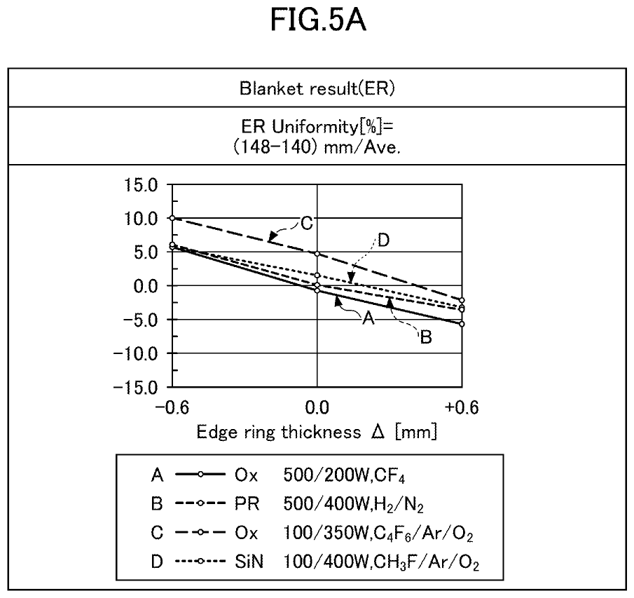

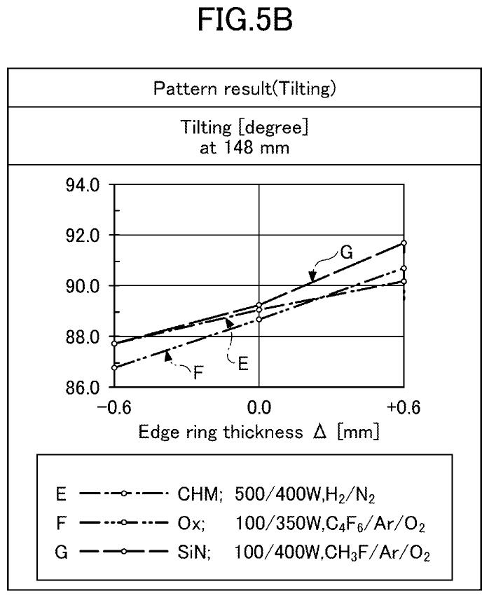

Next, a relationship between a thickness of an edge ring and etching characteristics will be described with reference to FIGS. 5A to 5C. FIGS. 5A to 5C are diagrams illustrating an example of a result of an experiment about a relationship between a thickness of the edge ring according to the present embodiment and etching characteristics. With respect to a graph in FIG. 5A, a horizontal axis indicates a difference between a thickness of the edge ring and a reference value of a thickness of the edge ring, and a vertical axis indicates uniformity of an etching rate. With respect to a graph in FIG. 5B, a horizontal axis indicates the difference between a thickness of the edge ring and the reference value of a thickness of the edge ring, and a vertical axis indicates tilting.

A value of the vertical axis in FIG. 5A represents a difference in an amount of deviation of an average of etching rates in an edge portion VE of a wafer W from a reference amount. Note that the edge portion VE is an outermost region on the wafer W, which is 140 mm to 148 mm away from a center of the wafer W, as illustrated in FIG. 5C. A value of the vertical axis in FIG. 5B represents an angle of an etching profile at a location 148 mm away from the center of the wafer W. Note that a graph in FIG. 5C indicates an example of etching rates when an antireflection film 203 or a silicon oxide film 201 was etched.

A layered film that was used for the experiment in FIG. 5A and FIG. 5B will be described. An example of a layered structure of a film that was etched in the present experiment is illustrated in FIG. 5C. In the layered structure of the film, from the bottom layer, the silicon oxide film (Ox) 201, a carbon hard mask (CHM) 202, and the antireflection film (SA) 203 are sequentially formed. A photoresist (PR) 204 pattern is formed on the antireflection film 203, which functions as a mask. Note that, in the present experiment, an evaluation of etching a layered structure, in which a silicon nitride film (SiN) is formed instead of the silicon oxide film 201, was also performed.

The graph in FIG. 5A illustrates to what degree an average of measured etching rates in the edge portion VE of the wafer W deviates from a reference amount, which indicates degree of uniformity of the etching rate. The graph in FIG. 5B illustrates an angle of the measured etching profile at a location 148 mm away from the center of the wafer W. By seeing a deviation of the angle from a reference value (90 degrees, which means that an etching profile is vertical), a tilting state can be recognized.

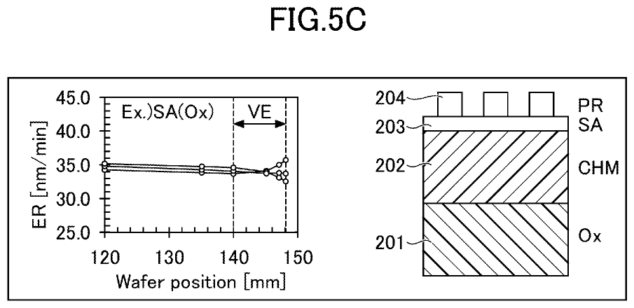

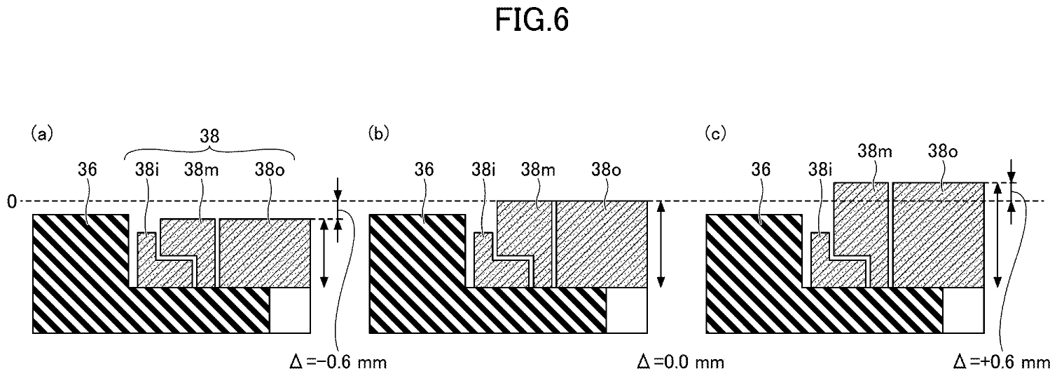

The horizontal axes in FIGS. 5A and 5B indicates a difference of a thickness (height) of the middle edge ring 38m and the outer edge ring 38o, based on a height of the middle edge ring 38m and the outer edge ring 38o illustrated in a diagram (b) in FIG. 6. Thus, a value 0.0 on the horizontal axis corresponds to the middle edge ring 38m and the outer edge ring 38o illustrated in the diagram (b) in FIG. 6. A value −0.6 on the horizontal axes in FIGS. 5A and 5B indicates that a height of the middle edge ring 38m and the outer edge ring 38o is 0.6 mm smaller than that illustrated in the diagram (b), as illustrated in a diagram (a) of FIG. 6. A value 0.6 on the horizontal axes in FIGS. 5A and 5B indicates that a height of the middle edge ring 38m and the outer edge ring 38o is 0.6 mm higher than that illustrated in the diagram (b), as illustrated in a diagram (c) of FIG. 6.

Curves A to D in FIG. 5A were obtained by performing etching processes while changing process conditions. The process conditions when the curves A to D were obtained will be described below.

### Curve A

The curve A represents an example of a result of an experiment in which the silicon oxide film 201 was etched by supplying CF₄ gas, while the high frequency electric power HF and the high frequency electric power LF were set to 500 W and 200 W respectively.

### Curve B

The curve B represents an example of a result of an experiment in which the photoresist 204 was etched by supplying H₂ gas and N₂ gas, while the high frequency electric power HF and the high frequency electric power LF were set to 500 W and 400 W respectively.

### Curve C

The curve C represents an example of a result of an experiment in which the silicon oxide film 201 was etched by supplying C₄F₆ gas, Ar gas, and O₂ gas, while the high frequency electric power HF and the high frequency electric power LF were set to 100 W and 350 W respectively.

### Curve D

The curve D represents an example of a result of an experiment in which the silicon nitride film was etched by supplying CHF gas, Ar gas, and O₂ gas, while the high frequency electric power HF and the high frequency electric power LF were set to 100 W and 400 W respectively.

From the curves A to D, it is found that a thickness of the edge ring 38 that can make an etching rate on an edge portion of a wafer W uniform (that is, a thickness of the edge ring 38 that can make an etching rate close to the reference amount) differs depending on a type of film to be etched, or a process condition such as a type of gas.

Curves E to G in FIG. 5B were obtained by performing etching processes while changing process conditions. The process conditions when the curves E to G were obtained will be described below.

### Curve E

The curve E represents an example of a result of an experiment in which the carbon hard mask 202 was etched by supplying H₂ gas and N₂ gas, while the high frequency electric power HF and the high frequency electric power LF were set to 500 W and 400 W respectively.

### Curve F

The curve F represents an example of a result of an experiment in which the silicon oxide film 201 was etched by supplying C₄F₆ gas, Ar gas, and O₂ gas, while the high frequency electric power HF and the high frequency electric power LF were set to 100 W and 350 W respectively.

### Curve G

The curve G represents an example of a result of an experiment in which the silicon nitride film was etched by supplying CH₃F gas, Ar gas, and O₂ gas, while the high frequency electric power HF and the high frequency electric power LF were set to 100 W and 400 W respectively.

From the curves E to G, it is found that a thickness of the edge ring 38 that can make a vertical (an angle of 90 degrees) etching profile at a location of an edge portion (148 mm) of a wafer W differs depending on a type of film to be etched, or a process condition such as a type of gas.

This is because a thickness of a sheath on a wafer W and the edge ring 38 differs depending on a type of film to be etched, or a process condition such as a type of gas. Thus, in a plasma etching method according to the present embodiment, the middle edge ring 38m is moved vertically at a time between one step and another step performed during a multi-step etching, to control a thickness of a sheath on the edge ring 38 in accordance with a type of film to be etched or a process condition. Accordingly, etching rate and tilting can be controlled appropriately in accordance with a type of film to be etched or a process condition.

Note that, in the plasma etching method according to the present embodiment, the middle edge ring 38m may be moved vertically at a time after a first etching step and before a second etching step in a multi-step etching.

Alternatively the middle edge ring 38m may be moved vertically after a first etching step for processing a first wafer W and before a second etching step for processing a second wafer W.

### Vertical Displacement Control of Edge Ring and Etching Characteristics

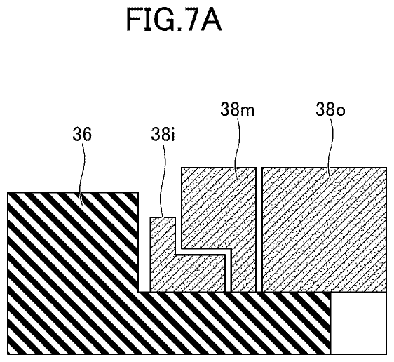

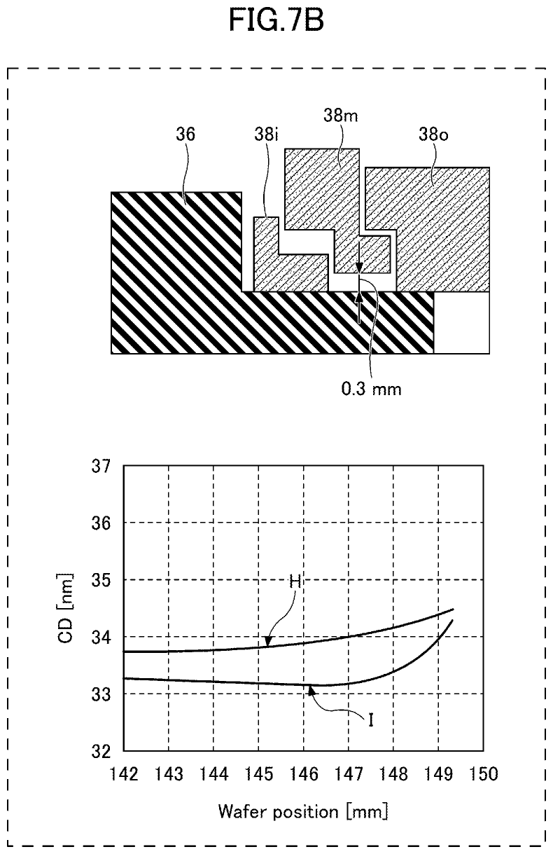

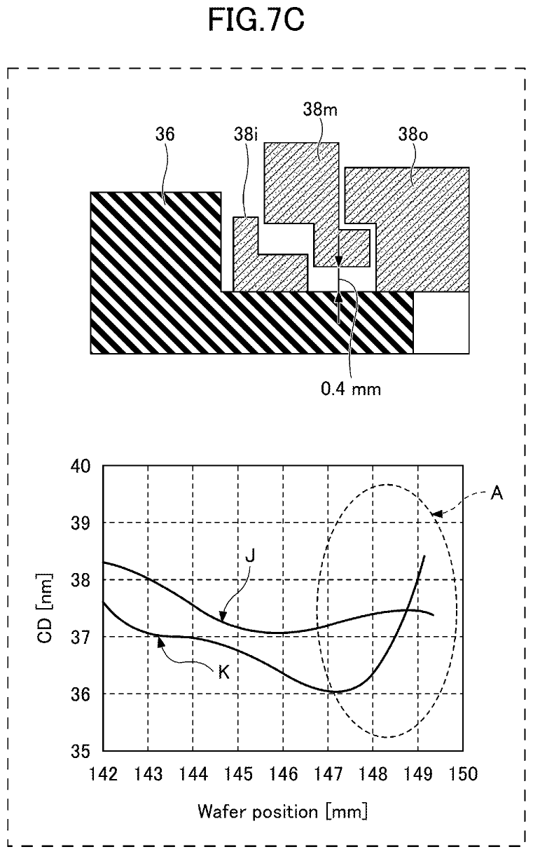

FIGS. 7A to 7C are diagrams illustrating an example of a result of an experiment about a relationship between vertical displacement of the middle edge ring 38m according to the present 1p embodiment and an etching characteristic. In this experiment, the layered structure on a wafer W illustrated in FIG. 5C was etched. However, when etching the antireflection film 203 illustrated in FIG. 5C, the middle edge ring 38m was not moved vertically (0 mm), as illustrated in FIG. 7A.

When the carbon hard mask 202 was etched after a step of etching the antireflection film 203, the middle edge ring 38m was moved upward to a position 0.3 mm above the upper surface of the electrostatic chuck 36. Further, when the silicon oxide film 201 was etched after a step of etching the carbon hard mask 202, the middle edge ring 38m was moved upward to a position 0.4 mm above the upper surface of the electrostatic chuck 36. Note that, in this experiment, the inner edge ring 38i and the outer edge ring 38o were fixed, and they were not moved vertically.

Curves H and J, illustrated in FIGS. 7B and 7C respectively, represent critical dimension (CD) values having been measured at an edge portion of the wafer W when the middle edge ring 38m was moved vertically. Conversely, Curves I and K, illustrated in FIGS. 7B and 7C respectively, represent CD values having been measured at the edge portion of the wafer W when the middle edge ring 38m was not moved vertically (0 mm). The CD value is an example of an etching characteristic.

According to the present experiment, it was found that, in an edge portion, a sharp increase in CD values indicated by the curves H and C is smaller than that indicated by curves I and K, and that the CD values indicated by the curves H and LT can be controlled to be uniform, by moving the middle edge ring 38m to an appropriate vertical position. Especially, as illustrated in a region A in a graph of FIG. 7C, which represents CD values in an area approximately 148 mm away from a center of the wafer W, a sharp increase in CD values of the curve J is suppressed as compared with the curve K, and uniformity of CD values improves.

There is a correlation between a CD value and an etching rate. Therefore, according to the aforementioned experimental results, it was found that uniformity of an etching rate can be improved by moving the middle edge ring 38m to an appropriate vertical position.

Similarly, there is a correlation between a CD value and tilting. Therefore, according to the aforementioned experimental results, it was found that tilting can be controlled by moving the middle edge ring 38m to an appropriate vertical position and that that an etching profile can be controlled to be vertical.

That is, it was found that, in a multi-step etching process, by controlling vertical movement of the edge ring 38 after a certain etching step and before the next etching step, an etching rate and an etching profile in an edge portion of a wafer W can be controlled appropriately.

In order to control an etching profile and an etching rate, the middle edge ring 38m may be moved vertically in accordance with a degree of abrasion of the edge ring. Alternatively, the middle edge ring 38m can be moved vertically regardless of a degree of abrasion of the edge ring, to control an etching profile and an etching rate.

Further, in the plasma etching method according to the present embodiment, by controlling vertical movement of the middle edge ring 38m, an etching rate in not only an edge portion of a wafer W but also an entirety of the wafer W can be shifted.

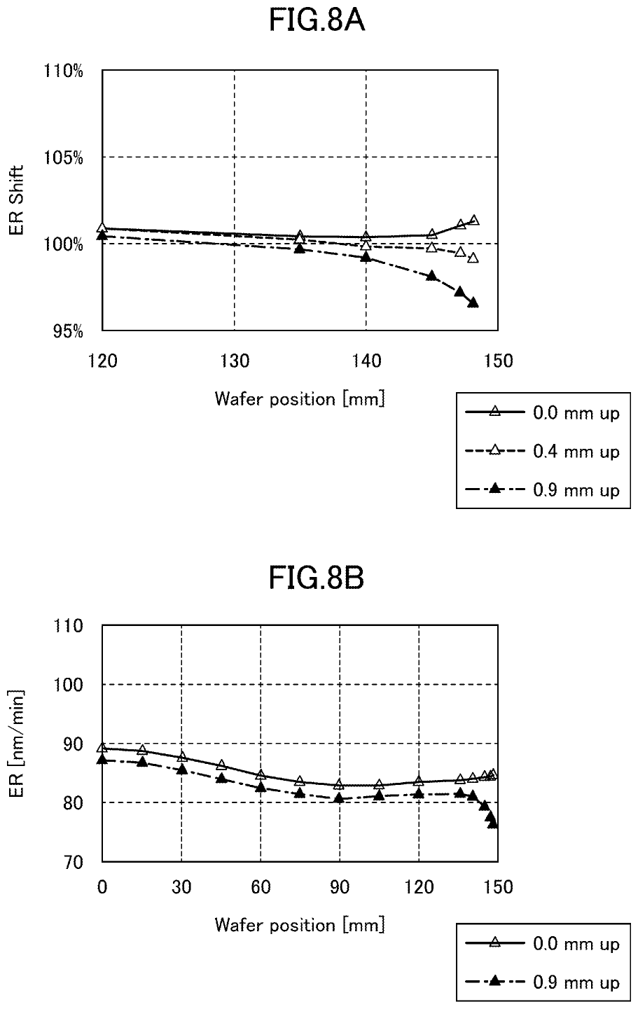

FIGS. 8A and 8B are diagrams illustrating an example of correlation information representing a relationship between vertical displacement of the middle edge ring 38m according to the present embodiment and an etching characteristic. FIG. 8A illustrates shift rates of an etching rate at multiple points on a region of a wafer W from a location 120 mm away from a center of the wafer W to a location 150 mm away from the center, which were measured by changing vertical positions of the middle edge ring 38m. A solid-line curve (0.0 mm up) in FIG. 8A represents a case in which the middle edge ring 38m was not moved, a broken-line curve in FIG. 8A (0.4 mm up) represents a case in which the middle edge ring 38m was moved upward by 0.4 mm, and a dash-dot-line curve in FIG. 8A (0.9 mm up) represents a case in which the middle edge ring 38m was moved upward by 0.9 mm. FIG. 8B illustrates etching rates at multiple points on a wafer W from a center of the wafer to a location 150 mm away from the center, which were measured by changing vertical Positions (0.0 mm, 0.9 mm up) of the middle edge ring 38m. A solid-line curve (0.0 mm up) in FIG. 8B represents a case in which the middle edge ring 38m was not moved, and a dash-dot-line curve in FIG. 8B (0.9 mm up) represents a case in which the middle edge ring 38m was moved upward by 0.9 mm.

According to a result in FIGS. 8A, by moving the middle edge ring 38m upward by 0.4 mm or 0.9 mm, it is found that an etching rate on an edge portion of a wafer W can be adjusted, from an etching rate in a case in which the middle edge ring 38m is not moved (0 mm up).

Also, according to a result in FIGS. 8B, by moving the middle edge ring 38m upward by 0.9 mm, it is found that an etching rate on an entire wafer W can be adjusted, from an etching rate in a case in which the middle edge ring 38m is not moved (0 mm up).

As described above, according to the plasma etching method of the present embodiment, by making a fine adjustment of vertical displacement amount of the middle edge ring 38m, an etching rate on an entire wafer W can be adjusted. Thus, it is found that the plasma etching method according to the present embodiment is useful for adjusting for differences with respect to the plasma processing apparatus 5.

### Correlation Information Collecting Process

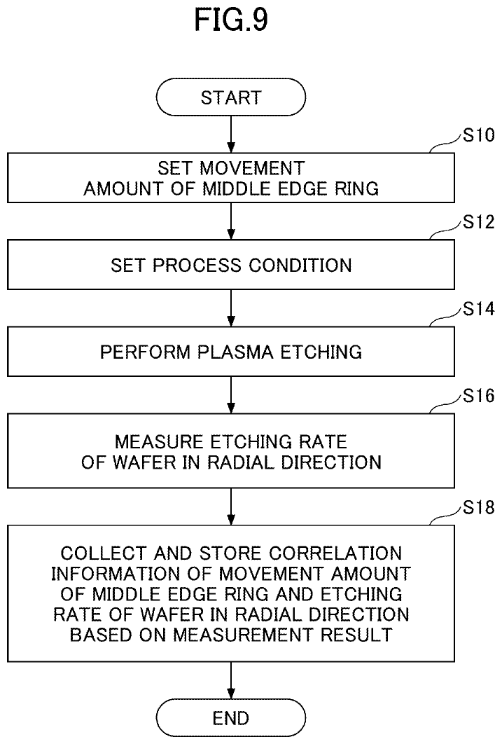

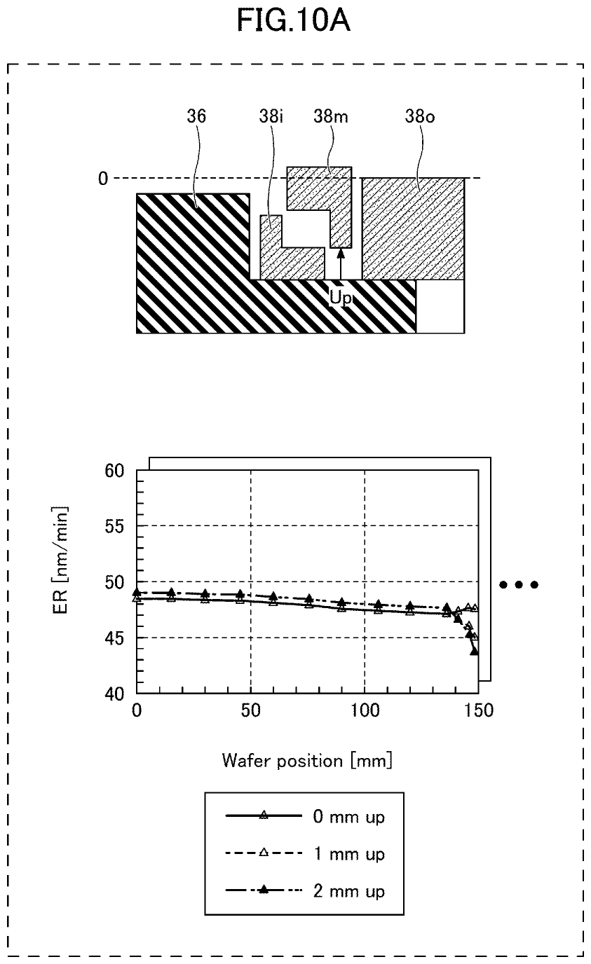

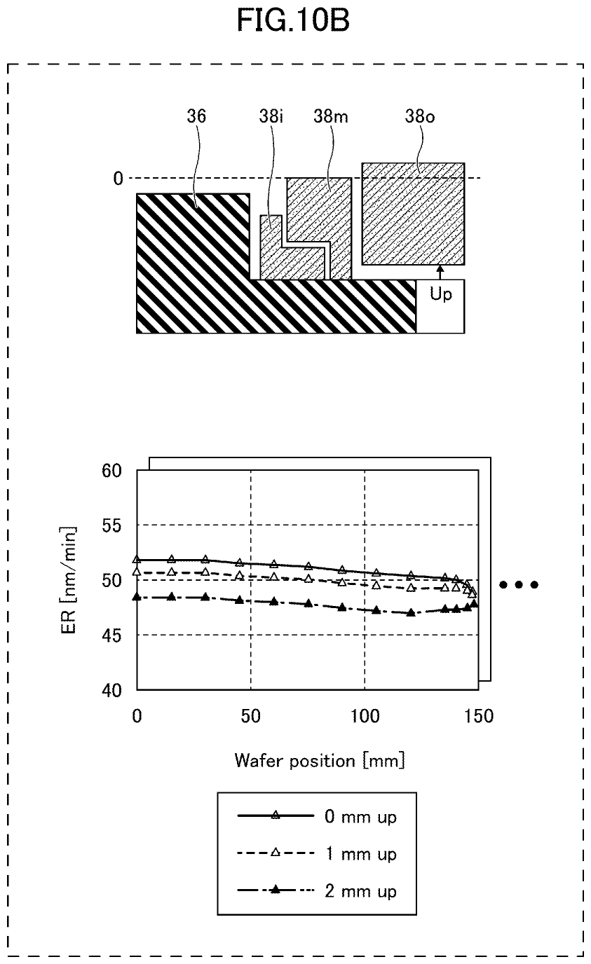

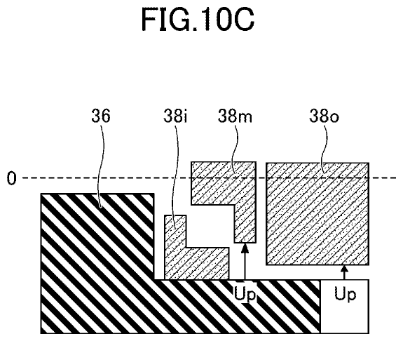

Next, a process of collecting correlation information representing a relationship between vertical displacement of the middle edge ring 38m according to the present embodiment and an etching characteristic will be described with reference to FIG. 9, and FIG. 10A. FIG. 9 is a flowchart illustrating an example of a correlation information collecting process (the process of collecting correlation information representing a relationship between vertical displacement of the middle edge ring according to the present embodiment and the etching characteristic). FIG. 10A illustrates an example of collected correlation information according to the present embodiment. Note that process conditions for an experiment to obtain the correlation information in FIG. 10A are as follows:

### Process Conditions

### Pressure: 50 mT (6.666 Pa)

High Frequency Electric Power HF: 500 W (applied to upper electrode)
High Frequency Electric Power LF: 150 W (applied to lower electrode)

Gas Type: CF₄ gas

Film to be etched: SiO₂

The correlation information collecting process in FIG. 9 is executed by the control unit 74. When the process is started, the control unit 74 sets vertical movement amount of the middle edge ring 38m of the plasma processing apparatus 5 (step S10). In accordance with the vertical movement amount set by the control unit 74, the middle edge ring 38m moves vertically (upward or downward). Next, the control unit 74 sets the process conditions of the process performed by the plasma processing apparatus 5 (step S12). Next, the control unit 74 performs a plasma etching process using the plasma processing apparatus 5, in accordance with the process conditions set at step S12 (step S14).

Next, the control unit 74 controls measurement of etching rates on a wafer in a radial direction (step S16). Next, based on the measurement result, the control unit 74 records correlation information (a set of the measured etching rates on the wafer in the radial direction and the vertical movement amount of the middle edge ring 38m) into the library 74e in the RAM 74c, by associating with the process condition (step S18), and terminates the process. The process in FIG. 9 is repeatedly executed by changing the vertical movement amount of the middle edge ring 38m (at step S10), and by changing process conditions (at step S12).

According to the correlation information collecting process, correlation information representing a relationship between an amount of vertical displacement of the middle edge ring 38m and etching rates of various points on a wafer which are dispersed in a radial direction of the wafer can be collected.

### Etching Process

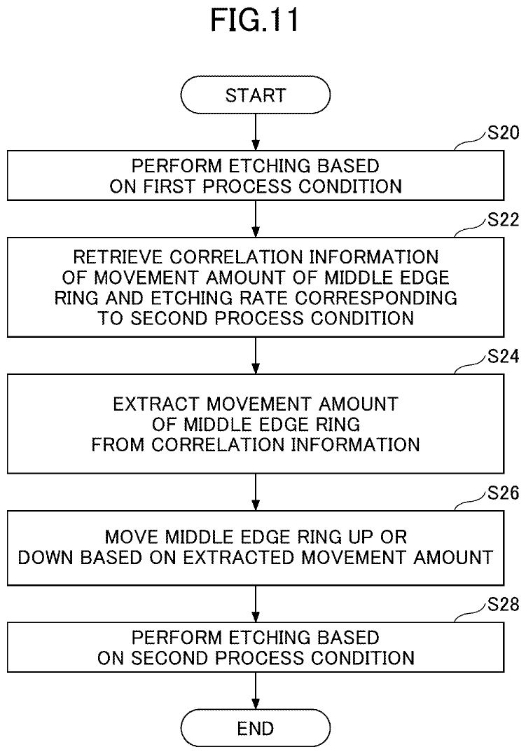

Next, an etching process according to the present embodiment will be described with reference to FIG. 11. FIG. 11 is a flowchart illustrating an example of the etching process according to the present embodiment.

The etching process in FIG. 11 is executed by the control unit 74. When the process is started, the control unit 74 performs a plasma etching process based on a first process condition (step S20). Next, the control unit 74 acquires, from the library 74e, the correlation information representing the relationship between an amount of vertical movement of the middle edge ring 38m and etching rates of a wafer in a radial direction, which corresponds to a second process condition (step S22).

Next, from the acquired correlation information, the control unit 74 extracts an amount of vertical movement of the middle edge ring 38m corresponding to an etching rate to be realized (step S24). Next, the control unit 74 moves the middle edge ring 38m vertically by the extracted amount of vertical movement (step S26). Lastly, the control unit 74 performs a plasma etching process based on the second process condition (step S28), and terminates the process.

According to the plasma etching method in the present embodiment, an etching state during a plasma etching process can be controlled by moving the middle edge ring 38m upward or downward. A height of the middle edge ring 38m that can make an etching rate on an edge portion of a wafer W uniform differs depending on a type of film to be etched or a process condition. This is because a thickness of a sheath on a wafer W and the edge ring 38 differs depending on a process condition and the like.

According to the plasma etching method in the present embodiment, the correlation information corresponding to a specific process condition is acquired from the library 74e, and an appropriate amount of vertical movement of the middle edge ring 38m is extracted from the acquired correlation information. By controlling movement of the middle edge ring 38m based on the extracted amount of vertical movement, etching can be controlled to a desired etching rate. Accordingly, a sharp increase of an etching rate at an edge portion of a wafer W can be suppressed, and a uniform etching rate can be attained.

Note that, in the description of FIG. 9 or FIG. 11, a case in which only the middle edge ring 38m is vertically moved is described. However, in another embodiment, the outer edge ring 38o may be moved vertically. For example, as illustrated in FIG. 10B, by measuring and collecting correlation information representing a relationship between an amount of displacement of the outer edge ring 38o and etching rates of a wafer in a radial direction, the outer edge ring 38o may be moved vertically based on the collected correlation information. This correlation information may also be stored in the library 74e in the RAM 74c of the control unit 74. Note that the correlation information illustrated in FIG. 10B was also collected by performing an experiment under the same process conditions as the process conditions used when the correlation information in FIG. 10A was collected.

Similarly, as illustrated in FIG. 10C, at least one of the middle edge ring 38m and the outer edge ring 38o may be moved vertically. Further, at least one of the inner edge ring 38i, the middle edge ring 38m, and the outer edge ring 38o may be moved vertically.

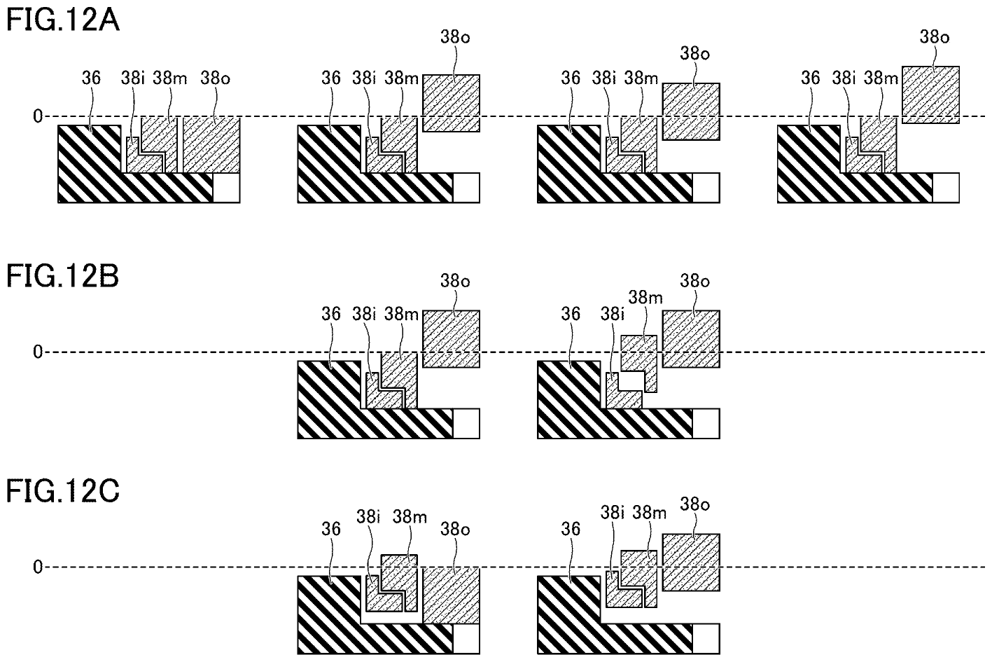

FIGS. 12A to 12C are diagrams illustrating variations of vertical movement of each piece of the edge ring 38. FIG. 12A illustrates a case in which none of the pieces of the edge ring 38 is moved at a first etching step (a leftmost diagram), and in which the outer edge ring 38o is moved vertically between the first etching step and a second etching step, between the second etching step and a third etching step, and between the third etching step and a fourth etching step (second, third, and fourth diagrams from the left). In FIG. 12A, although the middle edge ring 38m and the inner edge ring 38i are not moved, at least one of the middle edge ring 38m and the inner edge ring 38i may be moved when necessary.

FIG. 12B illustrates a case in which the outer edge ring 38o is moved at a first etching step (a left diagram), and in which the middle edge ring 38m and the outer edge ring 38o are moved vertically between the first etching step and a second etching step (a right diagram). In FIG. 12B, although the inner edge ring 38i is not moved, the inner edge ring 38i may be moved when necessary.

FIG. 12C illustrates a case in which the middle edge ring 38m and the outer edge ring 38o are moved at a first etching step (a left diagram), and in which the outer edge ring 38o is also moved vertically between the first etching step and a second etching step (a right diagram).

By moving the middle edge ring 38m vertically, etching of an edge portion of a wafer W can mainly be controlled, and by moving the outer edge ring 38o vertically, an etching rate of an entirety of a wafer W can be shifted. Accordingly, a state of etching can be controlled.

Alternatively, in addition to the middle edge ring 38m and the outer edge ring 38o, the inner edge ring 38i may be moved, and a state of etching may be controlled by combinations of movements of these pieces. In this case, as described above, correlation information of an amount of displacement of the inner edge ring 38i and an etching rate is collected and stored into the library 74e in advance, and during etching, vertical movement of each of the pieces of the edge ring 38 may be controlled based on the correlation information corresponding to a process condition.

### MODIFIED EXAMPLE

In the aforementioned embodiment, based on correlation information of a measured etching rate of a wafer W for production and a displacement amount of at least one of the pieces of the edge ring 38, vertical movement of at least one of the pieces of the edge ring 38 is controlled. However, correlation information is not limited to that in the aforementioned description. For example, based on correlation information of a measured etching rate of a dummy wafer (different from a wafer for production) and a displacement amount of the edge ring 38, vertical movement of at least one of the pieces of the edge ring 38 may be controlled to etch a wafer for production.

Alternatively, a thickness of a sheath on a wafer W and a thickness of a sheath on the edge ring 38 (or a difference between a thickness of a sheath on a wafer W and a thickness of a sheath on the edge ring 38) may be monitored, and vertical movement of at least one of the pieces of the edge ring 38 may be controlled based on the monitored information.

Further, controlling vertical movement of at least one of the pieces of the edge ring 38 is not necessarily performed only between a first etching step and a second etching step. For example, when performing pre-coating, there may be a case in which a height of the edge ring 38 varies as time passes, because byproduct generated during an etching process is deposited on the edge ring 38.

In a case in which a height of the edge ring 38 varies during etching as described above, vertical movement control of at least one of the pieces of the edge ring 38 may be performed with elapse of time, even during a single etching process. By moving at least one of the pieces of the edge ring 38 vertically, a sheath on the edge ring 38 can be controlled to an appropriate thickness, and a more appropriate etching process corresponding to a process condition can be performed.

The plasma etching method and the plasma processing apparatus according to the embodiment described above should be understood to be exemplary and not to be restrictive. Various changes or enhancements to the aforementioned embodiment can be made without departing from the spirit and scope of the claims. Matters described in the above embodiment may be changed to other configurations, and may be combined unless inconsistency occurs.

The plasma processing apparatus according to the present disclosure can be applicable to any type of plasma processing apparatuses, such as a capacitively coupled plasma (CCP) type, an inductively coupled plasma (ICP) type, a radial line slot antenna type, an electron cyclotron resonance plasma (ECR) type, and a helicon wave plasma (HWP) type.

In the plasma processing apparatus 5 illustrated in FIG. 1, only a single actuation mechanism 200 for vertically moving the middle edge ring 38m is provided. However, additional actuation mechanisms for vertically moving the inner edge ring 38i and the outer edge ring 38o may be provided. In this case, a pusher pin for raising the inner edge ring 38i may be provided directly under the inner edge ring 38i, and a pusher pin for raising the outer edge ring 38o may be provided directly under the outer edge ring 38o. Further, by providing actuating units, such as piezo actuators, to these pusher pins respectively, the inner edge ring 38i, the middle edge ring 38m, and the outer edge ring 38o can be caused to move up and down independently.

With respect to movement control of the edge ring 38, a minimum unit of movement of the middle edge ring 38m is equal to a resolution of the actuating unit for the middle edge ring 38m, which is 0.006 mm. A maximum amount of movement of the middle edge ring 38m is smaller than a thickness of the middle edge ring 38m.

Also, for example, a minimum unit of movement of the outer edge ring 38o is equal to a resolution of the actuating unit for the outer edge ring 38o, which is 0.006 mm. A maximum amount of movement of the outer edge ring 38o is smaller than a thickness of the outer edge ring 38o.

Also, for example, a minimum unit of movement of the inner edge ring 38i is equal to a resolution of the actuating unit for the inner edge ring 38i, which is 0.006 mm. A maximum amount of movement of the inner edge ring 38i is smaller than a thickness of the inner edge ring 38i.

Further, in the plasma processing apparatus 5 of the present disclosure, high frequency electric power HF may be applied to the stage 12.

In this specification, a wafer W is referred to as an example of a substrate. However, the substrate is not limited to the wafer. Examples of the substrate may include various types of substrates used in an LCD (Liquid Crystal Display) or a FPD (Flat Panel Display), a CD substrate, or a printed circuit board.

What is claimed is:

1. A method of performing plasma etching by a plasma processing apparatus, the plasma processing apparatus including an edge ring including
an inner edge ring provided in a vicinity of a substrate to be placed on a stage,
a middle edge ring arranged outside the inner edge ring, the middle edge ring being configured to be moved vertically by an actuation mechanism, and
an outer edge ring arranged outside the middle edge ring,
the method comprising:
performing first etching based on a first process condition;
performing second etching based on a second process condition different from the first process condition; and
moving the middle edge ring by the actuation mechanism, the moving being performed after the first etching is performed and before the second etching is performed.

2. The method according to claim 1, the plasma processing apparatus further including a memory unit configured to store correlation information of an amount of movement of the middle edge ring and a value representing an etching characteristic of the substrate, in association with a process condition;
the method further comprising acquiring, from the memory unit, the correlation information corresponding to the second process condition; wherein
the moving of the middle edge ring is performed based on the correlation information acquired by performing the acquiring.

3. A method of performing plasma etching by a plasma processing apparatus, the plasma processing apparatus including an edge ring including
an inner edge ring provided in a vicinity of a substrate to be placed on a stage,
a middle edge ring arranged outside the inner edge ring, the middle edge ring being configured to be moved vertically by a first actuation mechanism, and
an outer edge ring arranged outside the middle edge ring, the outer edge ring being configured to be moved vertically by a second actuation mechanism
the method comprising:
performing first etching based on a first process condition;
performing second etching based on a second process condition different from the first process condition; and
moving at least one of the middle edge ring and the outer edge ring after the first etching is performed and before the second etching is performed.

4. The method according to claim 3, the plasma processing apparatus further including a memory unit configured to store correlation information of an amount of movement of at least one of the middle edge ring and the outer edge ring and a value representing an etching characteristic of the substrate, in association with a process condition;
the method further comprising acquiring, from the memory unit, the correlation information corresponding to the second process condition; wherein
the moving of at least one of the middle edge ring and the outer edge ring is performed based on the correlation information acquired by performing the acquiring.

5. The method according to claim 1, the plasma processing apparatus further including an actuating unit configured to move the actuation mechanism vertically, a resolution of the actuating unit being 0.006 mm.

6. The method according to claim 5, wherein
a minimum unit of movement of the middle edge ring is equal to the resolution of the actuating unit, and
a maximum amount of movement of the middle edge ring is smaller than a thickness of the middle edge ring.

7. The method according to claim 3, the plasma processing apparatus further including a first actuating unit configured to move the first actuation mechanism vertically, and a second actuating unit configured to move the second actuation mechanism vertically, a resolution of each of the first actuating unit and the second actuating unit being 0.006 mm.

8. The method according to claim 7, wherein
a minimum unit of movement of the middle edge ring is equal to the resolution of the first actuating unit,
a minimum unit of movement of the outer edge ring is equal to the resolution of the second actuating unit,
a maximum amount of movement of the middle edge ring is smaller than a thickness of the middle edge ring, and
a maximum amount of movement of the outer edge ring is smaller than a thickness of the outer edge ring.

9. The method according to claim 1, wherein the first etching and the second etching are applied to a same substrate.

10. The method according to claim 1, wherein the first etching and the second etching are applied to different substrates respectively.

11. A plasma processing apparatus comprising:
a control unit configured to control etching applied to a substrate while changing process conditions; and
an edge ring including
an inner edge ring provided in a vicinity of the substrate to be placed on a stage,
a middle edge ring arranged outside the inner edge ring, the middle edge ring being configured to be moved vertically by an actuation mechanism, and
an outer edge ring arranged outside the middle edge ring; wherein
the control unit is configured to perform
first etching based on a first process condition;
second etching based on a second process condition different from the first process condition; and
movement of the middle edge ring by the actuation mechanism, the movement being performed after the first etching is performed and before the second etching is performed.

12. The plasma processing apparatus according to claim 11, wherein the outer edge ring is configured to be moved vertically by another actuation mechanism.
